(19) United States
(12) Patent Application Publication
(10) Pub. No.: US 2026/0018578 A1
(43) Pub. Date: Jan. 15, 2026

(54) VERTICALLY INTEGRATED COMPUTING AND MEMORY SYSTEMS AND ASSOCIATED DEVICES AND METHODS

(71) Applicant: Micron Technology, Inc., Boise, ID (US)

(72) Inventors: Lingming Yang, Meridian, ID (US); Raghukiran Sreeramaneni, Frisco, TX (US); Nevil N. Gajera, Meridian, ID (US)

(21) Appl. No.: 19/261,840

(22) Filed: Jul. 7, 2025

Related U.S. Application Data
(60) Provisional application No. 63/669,083, filed on Jul. 9, 2024.

(51) Int. Cl. H01L 25/18; H01L 23/00; H01L 23/48; H01L 25/065; H10B 80/00; H10D 80/30

(52) U.S. Cl. CPC H01L 25/18; H01L 23/481; H01L 24/08; H01L 25/0657; H10B 80/00; H10D 80/30; H01L 24/16; H01L 2224/08146; H01L 2224/16235; H01L 2225/06541; H01L 2225/06565; H01L 2924/1432; H01L 2924/1436; H01L 2924/1438

(57) ABSTRACT

System-in-packages (SiPs) having vertically integrated processing units and combined high-bandwidth memory (HBM) devices, and associated devices and methods, are disclosed herein. In some embodiments, the SiP includes a processing unit and a HBM device carried by the processing unit. Further, the combined HBM device can include one or more volatile memory dies and one or more non-volatile memory dies. The SiP can also include a shared through silicon via (TSV) bus that electrically couples combined HBM device can also include a shared bus that is electrically coupled to each of the processing unit, the one or more volatile memory dies, and the one or more non-volatile memory dies to establish communication paths therebetween.

### CROSS-REFERENCE TO RELATED APPLICATION(S)

The present application claims priority to U.S. Provisional Patent Application No. 63/669,083, filed Jul. 9, 2024, the disclosure of which is incorporated herein by reference in its entirety.

### TECHNICAL FIELD

The present technology is generally related to computing and memory systems and more specifically to vertically integrated computing and memory systems for semiconductor packages.

### BACKGROUND

Microelectronic devices, such as memory devices, microprocessors, and other electronics, typically include one or more semiconductor dies mounted to a substrate and encased in a protective covering. The semiconductor dies include functional features, such as memory cells, processor circuits, imager devices, interconnecting circuitry, etc. To meet continual demands on decreasing size, wafers, individual semiconductor dies, and/or active components are typically manufactured in bulk, singulated, and then stacked on a support substrate (e.g., a printed circuit board (PCB) or other suitable substrates). The stacked dies can then be coupled to the support substrate (sometimes also referred to as a package substrate) through bond wires in shingle-stacked dies (e.g., dies stacked with an offset for each die) and/or through substrate vias (TSVs) between the dies and the support substrate.

### BRIEF DESCRIPTION OF THE DRAWINGS

FIG. 1 is a schematic diagram illustrating an environment that incorporates a high bandwidth memory architecture.

FIG. 2 is a schematic diagram illustrating an environment that incorporates a high bandwidth memory architecture in accordance with some embodiments of the present technology.

FIG. 3 is a partially schematic cross-sectional diagram of a system-in-package configured in accordance with some embodiments of the present technology.

FIG. 4 is a simplified schematic diagram of a system-in-package including an interface die in accordance with some embodiments of the present technology.

FIG. 5 is a simplified schematic diagram of a system-in-package omitting an interface die in accordance with some embodiments of the present technology.

FIG. 6 is a partially schematic exploded view of a combined high-bandwidth memory device configured in accordance with some embodiments of the present technology.

FIG. 7 is a flow diagram of a process for operating a system-in-package device in accordance with some embodiments of the present technology.

FIG. 8 is a flow diagram of a process for operating a combined high-bandwidth memory device in accordance with some embodiments of the present technology.

FIGS. 9A and 9B are flow diagrams of processes for powering a system-in-package device down and powering a system-in-package device up, respectively, using a combined high-bandwidth memory device in accordance with some embodiments of the present technology.

The drawings have not necessarily been drawn to scale. Further, it will be understood that several of the drawings have been drawn schematically and/or partially schematically. Similarly, some components and/or operations can be separated into different blocks or combined into a single block for the purpose of discussing some of the implementations of the present technology. Moreover, while the technology is amenable to various modifications and alternative forms, specific implementations have been shown by way of example in the drawings and are described in detail below. The intention, however, is not to limit the technology to the particular implementations described.

### DETAILED DESCRIPTION

High data reliability, high speed of memory access, lower power consumption, and reduced chip size are features that are demanded from semiconductor memory. In recent years, three-dimensional (3D) memory devices have been introduced. Some 3D memory devices are formed by stacking memory dies vertically, and interconnecting the dies using through-silicon (or through-substrate) vias (TSVs). Benefits of the 3D memory devices include shorter interconnects (which reduce circuit delays and power consumption), a large number of vertical vias between layers (which allow wide bandwidth buses between functional blocks, such as memory dies, in different layers), and a considerably smaller footprint. Thus, the 3D memory devices contribute to higher memory access speed, lower power consumption, and chip size reduction. Example 3D memory devices include Hybrid Memory Cube (HMC) and High Bandwidth Memory (HBM). For example, HBM is a type of memory that includes a vertical stack of dynamic random-access memory (DRAM) dies and an interface die (which, e.g., provides the interface between the DRAM dies of the HBM device and a host device).

In a system-in-package (SiP) configuration, HBM devices may be integrated with a host device (e.g., a graphics processing unit (GPU) and/or computer processing unit (CPU)) using a base substrate (e.g., a silicon interposer, a substrate of organic material, a substrate of inorganic material and/or any other suitable material that provides interconnection between GPU/CPU and the HBM device and/or provides mechanical support for the components of a SiP device), through which the HBM devices and host communicate. Because traffic between the HBM devices and host device resides within the SiP (e.g., using signals routed through the silicon interposer), a higher bandwidth may be achieved between the HBM devices and host device than in conventional systems. In other words, the TSVs interconnecting DRAM dies within an HBM device, and the silicon interposer integrating HBM devices and a host device, enable the routing of a greater number of signals (e.g., wider data buses) than is typically found between packaged memory devices and a host device (e.g., through a printed circuit board (PCB)). The high bandwidth interface within a SiP enables large amounts of data to move quickly between the host device (e.g., GPU/CPU) and HBM devices during operation. For example, the high bandwidth channels can be on the order of 1000 gigabytes per second (GB/s, sometimes also referred to as gigabits (Gb)). It will be appreciated that such high bandwidth data transfer between a GPU/CPU and the memory of HBM devices can be advantageous in various high-performance computing applications, such as video rendering, high-resolution graphics applications, artificial intelligence and/or machine learning (AI/ML) computing systems and other complex computational systems, and/or various other computing applications.

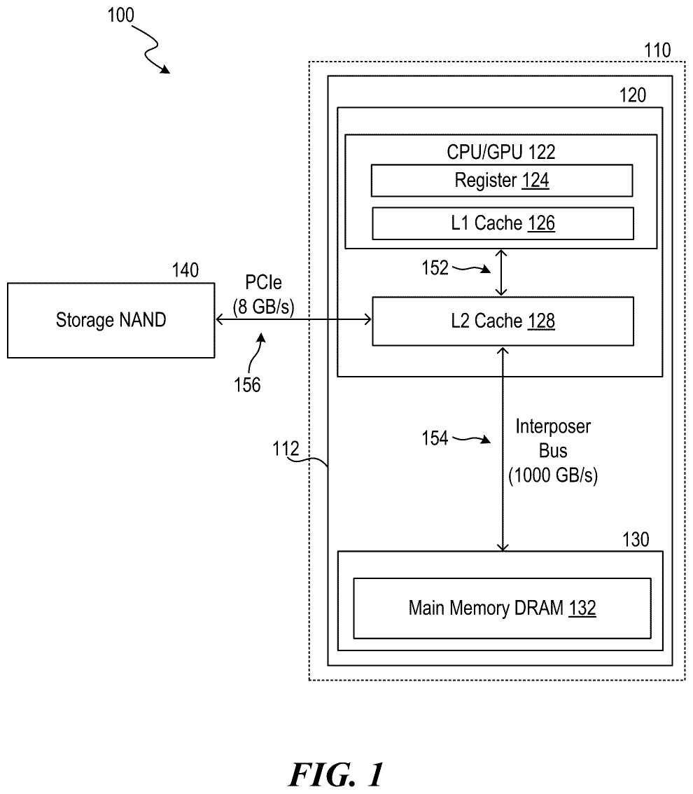

FIG. 1 is a schematic diagram illustrating an environment 100 that incorporates a high bandwidth memory architecture. As illustrated in FIG. 1, the environment 100 includes a SiP device 110 having one or more processing devices 120 (one illustrated in FIG. 1, sometimes also referred to herein as one or more “hosts”), and one or more HBM devices 130 (one illustrated in FIG. 1), integrated with a silicon interposer 112 (or any other suitable base substrate). The environment 100 additionally includes a storage device 140 coupled to the SiP device 110. The processing devices(s) 120 can include one or more CPUs and/or one or more GPUs, referred to as a CPU/GPU 122, each of which may include a register 124 and a first level of cache 126. The first level of cache 126 (also referred to herein as “L1 cache”) is communicatively coupled to a second level of cache 128 (also referred to herein as “L2 cache”) via a first communication path 152. In the illustrated embodiment, the L2 cache 128 is incorporated into the processing device(s) 120. However, it will be understood that the L2 cache 128 can be integrated into the SiP device 110 separate from the processing device(s) 120. Purely by way of example, the processing device(s) 120 can be carried by a base substrate (e.g., an interposer that is itself carried by a package substrate) adjacent to the L2 cache 128 and in communication with the L2 cache 128 via one or more signal lines (or other suitable signal route lines) therein. The L2 cache 128 may be shared by one or more of the processing devices 120 (and CPU/GPU 122 therein). During operation of the SiP device 110, the CPU/GPU 122 can use the register 124 and the L1 cache 126 to complete processing operations, and attempt to retrieve data from the larger L2 cache 128 whenever a cache miss occurs in the L1 cache 126. As a result, the multiple levels of cache can help accelerate the average time it takes for the processing device(s) 120 to access data, thereby accelerating the overall processing rates.

As further illustrated in FIG. 1, the L2 cache 128 is communicatively coupled to the HBM device(s) 130 through a second communication channel 154. As illustrated, the processing device(s) 120 (and the L2 cache 128 therein) and HBM device(s) 130 are carried by and electrically coupled (e.g., integrated by) the silicon interposer 112. The second communication channel 154 is provided by the silicon interposer 112 (e.g., the silicon interposer includes and routes the interface signals forming the second communication channel, such as through one or more redistribution layers (RDLs)). As additionally illustrated in FIG. 1, the L2 cache 128 is also communicatively coupled to a storage device 140 through a third communication channel 156. As illustrated, the storage device 140 is outside of the SiP device 110, and utilizes signal routing components that are not contained within the silicon interposer 112 (e.g., between a packaged SiP device 110 and packaged storage device 140). For example, the third communication channel 156 may be a peripheral bus used to connect components on a motherboard or PCB, such as a Peripheral Component Interconnect Express (PCIe) bus. As a result, during operation of the SiP device 110, the processing device(s) 120 can read data from and/or write data to the HBM device(s) 130 and/or the storage device 140, through the L2 cache 128.

In the illustrated environment 100, the HBM devices 130 include one or more stacked volatile memory dies 132 (e.g., DRAM dies, one illustrated schematically in FIG. 1) coupled to the second communication channel 154. As explained above, the HBM device(s) 130 can be located on the silicon interposer 112, on which the processing device(s) 120 are also located. As a result, the second communication channel 154 can provide a high bandwidth (e.g., on the order of 1000 GB/s) channel through the silicon interposer 112. Further, as explained above, each HBM device(s) 130 can provide a high bandwidth channel (not shown) between the volatile memory dies 132 therein. As a result, data can be communicated between the processing device(s) 120 and the HBM device(s) 130 (and the volatile memory dies 132 therein) at high speeds, which can be advantageous for data-intensive processing operations. Although the HBM device(s) 130 of the SiP device 110 provide relatively high bandwidth communication, their integration on the silicon interposer 112 suffers from certain shortcomings. For example, each HBM device(s) 130 may provide a limited amount of storage (e.g., on the order of 16 GB each), where the total storage provided by all of the HBM devices 130 may be insufficient to maintain the working data set of an operation to be performed by the SiP device 110. Additionally, or alternatively, the HBM device(s) 130 are made up of volatile memory (e.g., each requires power to maintain the stored data, and the data is lost once the HBM device is powered down and/or suffers an unexpected power loss).

In contrast to the characteristics of the HBM devices 130, the storage device 140 can provide a large amount of storage (e.g., on the order of terabytes and/or tens of terabytes). The greater capacity of the storage device 140 is typically sufficient to maintain the working data set of the complex operations to be performed by the SiP device 110. Additionally, the storage device 140 is typically non-volatile (e.g., made up of NAND-based storage, such as NAND flash, as illustrated in FIG. 1), and therefore retains stored data even after power is lost. However, as discussed above, the storage device 140 is located external to the SiP device 110 (e.g., not placed on the silicon interposer 112), and instead coupled to the SiP device 110 through a communication channel (e.g., PCIe) routed over a motherboard, system board, or other form of PCB. As a result, the third communication channel 156 can have a relatively low bandwidth (e.g., on the order of 8 GB/s), significantly lower than the bandwidth of the second communication channel 154. Consequently, processing operations involving large amounts of data (e.g., graphics rendering, AI/ML processes, and the like), which do not fit within the storage capacities of the HBM device 130, are bottlenecked by the low bandwidth of the third communication channel 156 as data moves between the storage device 140 and the SiP device 110. Additionally, power-down/power-up operations that require data to move between the storage device 140 and the SiP device 110 are bottlenecked by the relatively low bandwidth of the third communication channel 156.

Vertically integrated computing and memory systems, and associated devices and methods, that address the shortcomings discussed above are disclosed herein. A vertically integrated computing and memory system can include a host device and a HBM device. The HBM device can include one or more volatile memory dies (e.g., DRAM dies) and one or more non-volatile memory dies (e.g., NAND dies, NOR dies, PCM dies, FeRAM dies, MRAM dies, and/or any other suitable dies). The HBM device can optionally include a controller die for the one or more volatile memory dies and/or a controller die for the one or more non-volatile memory dies. The vertically integrated computing and memory system can also include one or more TSVs that electrically couple the host device to the volatile memory dies and to the non-volatile memory dies to establish communication paths therebetween. As described herein, the TSVs can provide a wide communication path (e.g., on the order of 1024 I/Os) between the volatile memory dies, the non-volatile memory dies, and the host device, enabling high bandwidth therebetween. In other words, the disclosed HBM device combines both volatile memory and non-volatile memory (referred to herein as a “combined HBM device”), while providing high-bandwidth communication between the memories within the combined HBM device as well as between the combined HBM device and the host device. As explained herein, embodiments of the combined HBM device may be vertically integrated with the host device. For example, combined HBM devices may be vertically stacked on top of the host device.

Advantageously, vertically integrating memories and host devices and creating communication paths therebetween using TSVs as opposed to, for example, a SiP bus with routes extending through an interposer die, can provide a higher bandwidth communication channel between the combined HBM devices and the host device. Additionally, vertically integrating memories and host devices can eliminate the need for certain components included in conventional SiPs, such as interposer dies and interface dies. Moreover, because multiple combined HBM devices can be stacked on top of a single host device, vertically integrated computing and memory systems provide significant space savings for valuable substrate real estate. Accordingly, embodiments of the present technology provide improved functionality, cost savings, and size reduction.

Furthermore, large sets of data can be loaded into the non-volatile memory dies (e.g., from an external storage component) through a low bandwidth communication path (e.g., PCIe) during an initialization phase. Then, during processing, portions of the large data set may be transferred between the non-volatile memory dies and the volatile memory dies via a high bandwidth communication path (e.g., a TSV bus) coupled therebetween, based on the portions of the large data set being processed at a time (e.g., the working data set). In this example, the volatile memory dies of the combined HBM device can provide functionality similar to the HBM device 130 discussed above with reference to FIG. 1. That is, for example, the volatile memory dies can provide DRAM-based storage of a working data set, accessible via a high bandwidth interface (e.g., the TSV bus) to the host devices. Once a first portion of the data set has been processed, a result can be saved to the non-volatile memory dies and a second portion of the data set can be loaded into the volatile memory dies, through the high bandwidth communication path, from the data set in the non-volatile memory dies. The process can then be repeated for the first, second, etc., portions of the data set to use the data set in any number of computations at the host device without needing to load the data set through the low bandwidth communication path.

In a specific, non-limiting example, the data set can include training data for an artificial intelligence and/or machine learning (AI/ML) model that needs to be accessed and/or processed hundreds, thousands, tens of thousands, or more of times to train the AI/ML model. In this example, the vertically integrated computing and memory system can significantly reduce the processing time by requiring the data set to only be communicated to the combined HBM device through the low bandwidth channel once during an initialization phase, and subsequently provide high bandwidth transfer of the data set (or portions thereof) between the volatile memory dies and the non-volatile memory dies of the combined HBM device, and between the host device and the combined HBM devices stacked thereon during a processing phase (e.g., reducing the processing time by hundreds of seconds, thousands of seconds, tens of thousands of seconds, or more).

Embodiments of the present technology can also improve the performance of AI/ML models compared to conventional SiPs by providing increased memory capacity, which typically limits the precision and batch size of such models. For example, the batch size has a critical impact on the convergence of the training process and the resulting accuracy of the trained model. Typically, there exists an optimal value or range of batch sizes for a given neural network and data set. If the batch size is too large, the trained model can exhibit poor generalization (or even get stuck at a local minimum). In other words, the trained model can exhibit overfitting and consequently perform poorly on samples outside the training set. Conversely, if the batch size is too small, the trained model can exhibit poor (slow) convergence speed. Fewer samples used at each training step can lead to noisier and less accurate gradient estimates. In other words, a small batch size will lead to a single sample having a (excessively) large impact on the applied variable updates, thereby extending the time it takes for the model to converge.

Additionally, or alternatively, the non-volatile memory dies can provide non-volatile storage for the data stored in the combined HBM device (e.g., the non-volatile memory dies operate as a non-volatile DRAM). In said embodiments, the non-volatile memory dies may not be usable by a host device (e.g., they may not increase the memory capacity that is made available to the host device and/or may not be used for their increase of memory capacity). In said embodiments, the non-volatile memory dies operating as non-volatile DRAM can save data from and restore data to the volatile memory dies in response to certain event, such as power-down and/or power-up. For example, in response to a power-down or idle request, data from the volatile memory dies and/or any of the caches can be stored in the non-volatile memory dies, in response to a power-down or idle request, to store a present state of the SiP device. Because the non-volatile memory dies are available through the high bandwidth communication path, the request can be satisfied much faster than communicating the data to a separate storage component (e.g., on the order of tens of milliseconds instead of several seconds). Similarly, in response to a power-up or wake-up request is received, the data can be moved back to the volatile memory dies and/or cache(s) through the high bandwidth communication paths. As a result, the saved state of the SiP can be restored, and the power-up request can be answered, within tens of milliseconds instead of the several seconds required when data must be loaded from the separate storage component.

Additional details on the vertically integrated computing and memory systems, and associated devices and methods, are set out below. For ease of reference, semiconductor packages (and their components) are sometimes described herein with reference to front and back, top and bottom, upper and lower, upwards and downwards, and/or horizontal plane, x-y plane, vertical, or z-direction relative to the spatial orientation of the embodiments shown in the figures. It is to be understood, however, that the semiconductor assemblies (and their components) can be moved to, and used in, different spatial orientations without changing the structure and/or function of the disclosed embodiments of the present technology. Additionally, signals within the semiconductor packages (and their components) are sometimes described herein with reference to downstream and upstream, forward and backward, and/or read and write relative to the embodiments shown in the figures. It is to be understood, however, that the flow of signals can be described in various other terminology without changing the structure and/or function of the disclosed embodiments of the present technology.

Further, although the memory device architectures disclosed herein are primarily discussed in the context of expanding memory capacity to improve artificial intelligence and machine learning models and/or to create non-volatile memory in a dynamic random-access memory (DRAM) component, one of skill in the art will understand that the scope of the technology is not so limited. For example, the systems and methods disclosed herein can also be deployed to expand the available high bandwidth memory for various other applications that process significant volumes of data (e.g., video rendering, decryption systems, and the like).

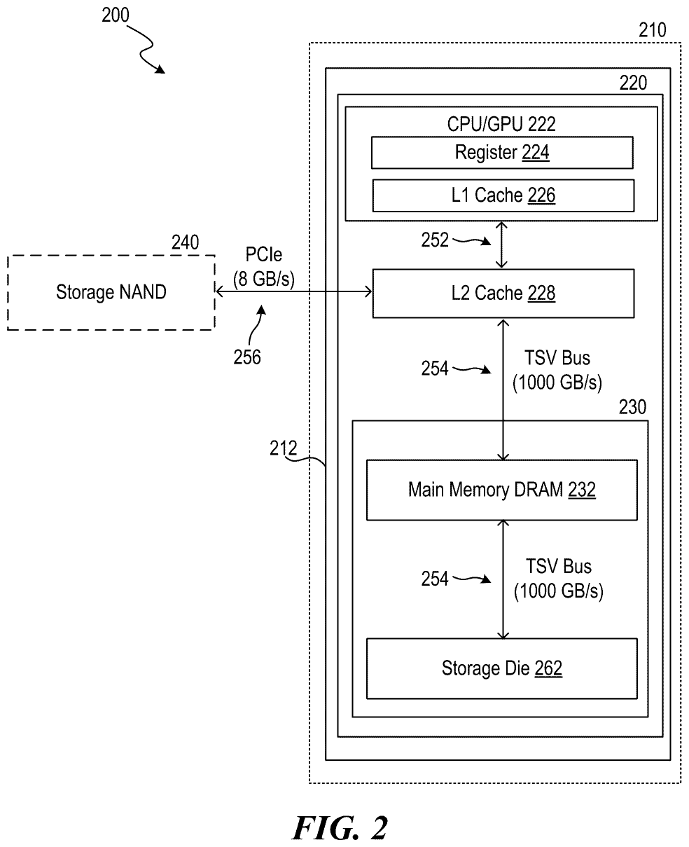

FIG. 2 is a schematic diagram illustrating an environment 200 that incorporates an HBM architecture in accordance with some embodiments of the present technology. Similar to the environment 100 discussed above, the environment 200 includes a SiP device 210 having one or more processing devices 220 (one illustrated in FIG. 2) and one or more combined HBM device(s) 230 (one illustrated in FIG. 2). As schematically shown, the combined HBM device(s) 230 can be integrated on the processing device(s) 220 (e.g., carried by the processing device(s) 220). Further, the processing device(s) 220 is integrated on an interposer 212 (e.g., a silicon interposer, another organic interposer, an inorganic interposer, and/or any other suitable base substrate). In some embodiments, however, the SiP device 210 does not include the interposer 212. The processing device(s) 220 is driven by a CPU/GPU 222 that includes a register 224 and an L1 cache 226. The L1 cache 226 is communicatively coupled to an L2 cache 228 via a first communication channel 252. The L2 cache 228 is communicatively coupled to a stack of one or more volatile memory dies 232 (e.g., DRAM dies) and a stack of one or more storage dies 262 (e.g., NAND dies, NOR dies, or other suitable non-volatile memory dies) in the combined HBM device(s) 230 through a second communication channel 254. The storage dies 262 can provide a relatively large storage capacity (e.g., on the order of hundreds of gigabytes and/or a terabyte), as well as non-volatile storage within the SiP device 210. The second communication channel 254 can comprise a TSV bus. The L2 cache 228 is also communicatively coupled to a storage device 240 through a third communication channel 256. The second communication channel 254 can have a relatively high bandwidth (e.g., on the order of 1000 GB/s) while the third communication channel 256 can have a relatively low bandwidth (e.g., on the order of 8 GB/s).

Accordingly, the combined HBM device(s) 230 provide the SiP device 210 with high bandwidth access to a large amount of non-volatile storage, rather than needing to access the storage devices 240 through the third communication channel 256. Although FIG. 2 illustrates an embodiment in which the storage dies 262 are coupled to the volatile memory dies 232 via the second communication channel 254, in some embodiments, the second communication channel 254 can additionally or alternatively couple the storage dies 262 to the processing device(s) 220, and/or an additional communication channel (not shown) can couple the storage dies 262 to the processing device(s) 220.

The combination of volatile memory and non-volatile memory (e.g., via the combined HBM device(s) 230) within the SiP device 210 can provide various advantages. For example, volatile memory such as DRAM typically provides accesses (e.g., reads and writes) that are relatively faster than non-volatile memory such as NAND, but at a lower density (e.g., storage capacity within a die footprint). In contrast, non-volatile memory such as NAND typically provides a high storage density, but can be relatively slow to access and can incur certain overheads (e.g., wear-leveling). As a result, the volatile memory dies 232 can provide low-latency fast communication, making data quickly available to the processing device(s) 220 of the SiP device 210 as needed. The non-volatile memory dies 262 can provide a relatively large memory capacity that is “closer” to the processing devices 220 (e.g., accessible within the SiP device 210 through high bandwidth buses, such as the second communication channel 254, and/or other communication channels not shown) as compared to the storage device 240 (e.g., accessible through the slower third communication channel 256, such as PCIe). Additionally, the non-volatile memory dies 262 can provide non-volatile memory capacity that is closer to the processing devices 220 and/or the volatile memory dies 232 as compared to the storage device 240 and/or other non-volatile memory capacity.

Furthermore, because the combined HBM device(s) 230 are integrated directly on the processing device(s) 220 (e.g., carried by the processing device(s) 220, as opposed to providing a communication channel therebetween through the interposer 212), the combined HBM device(s) 230 can provide volatile and non-volatile memory capacity that is “closer” to the processing devices 220 (e.g., accessible through high bandwidth buses, such as the second communication channel 254, and/or other communication channels not shown). As a result, for example, a relatively large data set can be communicated from the storage device 240 to the non-volatile memory dies 262 in the combined HBM device(s) 230 to initiate a processing operation (e.g., to run an AI/ML algorithm). For example, an entire data set needed for an AI/ML operation can be copied from the storage device 240 to the non-volatile memory dies 262. Subsets of the data set can then be rapidly communicated from the non-volatile memory dies 262 to the volatile memory dies 232, then to the processing device(s) 220 via the high bandwidth of the second communication channel 254 (sometimes also referred to herein as a “high bandwidth communication path”).

When the processing devices(s) 220 is finished processing the subset, a new subset can be quickly written into the volatile memory dies 232 from the non-volatile memory dies 262, without needing to retrieve the data from the storage device 240 with the attendant bottleneck in the third communication channel 256 (sometimes also referred to herein as a “low bandwidth communication path”). Further, the processing operation can be iteratively executed (e.g., the hundreds, thousands, tens of thousands, or more iterations often used for an AI/ML algorithm) without requiring the large data set to be communicated through the bottleneck multiple times. Thus, (i) the inclusion of the combined HBM device(s) 230 and (ii) the vertical integration of the combined HBM device(s) 230 on the processing device(s) 220 can increase the processing speed of the SiP device 210, thereby increasing the functionality of the environment 200. Further, because communicating data through high bandwidth channels is more efficient than communicating data through low bandwidth channels, the inclusion of the non-volatile memory dies 262 in the SiP device 210 can reduce the overall power consumption of the environment 200 and/or reduce the heat generated by the environment 200.

Additionally, or alternatively, the non-volatile memory die(s) 262 in the combined HBM device(s) 230 can save a copy of the data being processed and/or an overall state of the SiP device 210 in a non-volatile component. As a result, for example, the state of the HBM device(s) 230 does not need to be written between the volatile memory dies 232 and the non-volatile dies 262 to power down and/or power up. Instead, the state can be written to the non-volatile memory dies 262 in the combined HBM device(s) 230. Thus, a power-down operation (sometimes also referred to herein as a “sleep operation” and/or an “idle operation”) can be completed almost instantly (e.g., by saving a copy through the high bandwidth of the second communication channel 254). Similarly, a power-up operation (sometimes also referred to herein as a “wake up operation”) can write the state back to the volatile memory dies 232 from the non-volatile memory dies 262 in the combined HBM device(s) 230 via the second communication channel 254, instead of from the storage device 240 via the third communication channel 256. As a result, the power-down and/or power-up operations can be accelerated from several seconds to much less than one second (e.g., tens of milliseconds). Additionally, or alternatively, the combined HBM device(s) 230 can protect against a loss of power and/or other processing errors in the environment 200. For example, because the combined HBM device(s) 230 can save a current state of SiP device 210 (e.g., a current state of the combined HBM device(s) 230 and/or the processing device(s) 220) to the non-volatile dies 262 in milliseconds, the combined HBM device(s) 230 can save a current state of the SiP device 210 to the non-volatile dies 262 after a predetermined period (e.g., every ten seconds, minute, five minutes, thirty minutes, hour, two hours, twelve hours, day, and/or any other suitable period) and/or after various processing milestones without significantly delaying processing at the SiP device 210. As a result, a loss of power and/or other error can return to the last saved state before the loss of power and/or error, thereby losing less processing time and/or less data (e.g., restoring half of a processing operation rather than needing to start over).

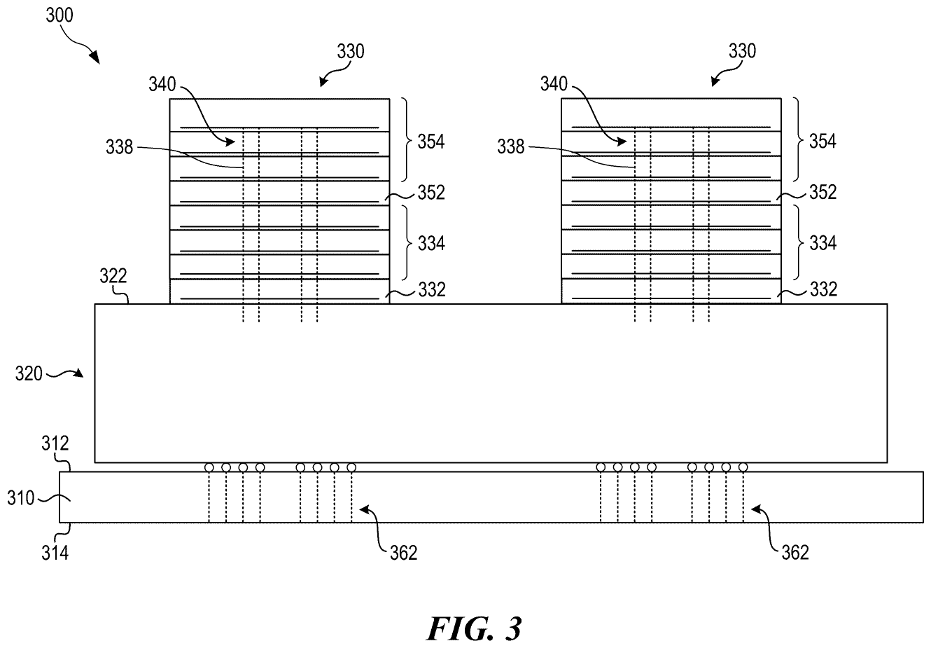

The environment 200 can be configured to perform any of a wide variety of suitable computing, processing, storage, sensing, imaging, and/or other functions. For example, representative examples of systems that include the environment 200 (and/or components thereof, such as the SiP device 210) include, without limitation, computers and/or other data processors, such as desktop computers, laptop computers, Internet appliances, hand-held devices (e.g., palm-top computers, wearable computers, cellular or mobile phones, automotive electronics, personal digital assistants, music players, etc.), tablets, multi-processor systems, processor-based or programmable consumer electronics, network computers, and minicomputers. Additional representative examples of systems that include the environment 200 (and/or components thereof) include lights, cameras, vehicles, etc. With regard to these and other examples, the environment 200 can be housed in a single unit or distributed over multiple interconnected units, e.g., through a communication network, in various locations on a motherboard, and the like. Further, the components of the environment 200 (and/or any components thereof) can be coupled to various other local and/or remote memory storage devices, processing devices, computer-readable storage media, and the like. Additional details on the architecture of the environment 200, the SiP device 210, the combined HBM device(s) 230, and processes for operation thereof, are set out below with reference to FIGS. 3-9B.

FIG. 3 is a partially schematic cross-sectional diagram of a SiP device 300 configured in accordance with some embodiments of the present technology. As illustrated in FIG. 3, the SiP device 300 includes a base substrate 310 (e.g., a silicon interposer, another suitable organic substrate, an inorganic substrate, and/or any other suitable material), a processing unit or host device 320 integrated with an upper surface 312 of the base substrate 310, and one or more combined HBM devices 330 integrated with an upper surface 322 of the host device 320. For example, as discussed in more detail below, the host device 320 and individual dies included in the combined HBM devices 330 are communicatively coupled by a TSV bus 340 extending therethrough and therebetween. The number of combined HBM devices 330 integrated with the upper surface 322 of a single host device 320 can be one, two, three, four, five, six, seven, eight, or more.

In the illustrated embodiments, the host device 320 is illustrated as a single component. However, as discussed above with reference to FIG. 2, the host device 320 can include a CPU/GPU component, a register, an L1 cache, an L2 cache, and/or various other suitable components integrated into a single package.

The combined HBM device 330 includes a stack of semiconductor dies. The stack of semiconductor dies in the combined HBM device 330 can include a first controller die 332, one or more volatile memory dies 334 (three illustrated in FIG. 3), a second controller die 352, and one or more non-volatile memory dies 354 (three illustrated in FIG. 3). The first controller die 332 can be operably coupled to manage operation of the volatile memory dies 334 and the second controller die 352 can be operably coupled to manage operation of the non-volatile memory dies 354. The first controller die 332, the volatile memory dies 334, the second controller die 352, and the non-volatile memory dies 354 can be integrated, or stacked, on one another. In the illustrated embodiment, the non-volatile memory dies 354 are stacked on top of the second controller die 352, the second controller die 352 is stacked on top of the volatile memory dies 334, the volatile memory dies 334 are stacked on top of the first controller die 332, and the first controller die 332 is stacked on top of the host device 320. In other embodiments, however, the dies of the combined HBM device 330 can be stacked in a different order or arrangement. In some embodiments, the combined HBM device 330 omits the first controller die 332 and/or the second controller die 352, and functionalities found in and/or operations performed by the first controller die 332 and/or the second controller die 352 can be included elsewhere, such as in the host device 320.

The dies of each combined HBM device 330 are coupled to one another and to the host device 320 via the TSV bus 340, which includes one or more TSVs 338 (four illustrated schematically in each combined HBM device 330 FIG. 3). The TSVs 338 (sometimes also referred to herein as part of (or forming) the TSV bus 340) extend from the host device 320 through each of the first controller die 332, the volatile memory dies 334, the second controller die 352, and the non-volatile memory dies 354. The TSVs 338 allow each of the dies to communicate data within the combined HBM device 330 (e.g., between the volatile memory dies 334 (e.g., DRAM dies) and the non-volatile memory dies 354 (e.g., NAND dies)) at a relatively high rate (e.g., on the order of 100 GB/s, 1000 GB/s, or greater).

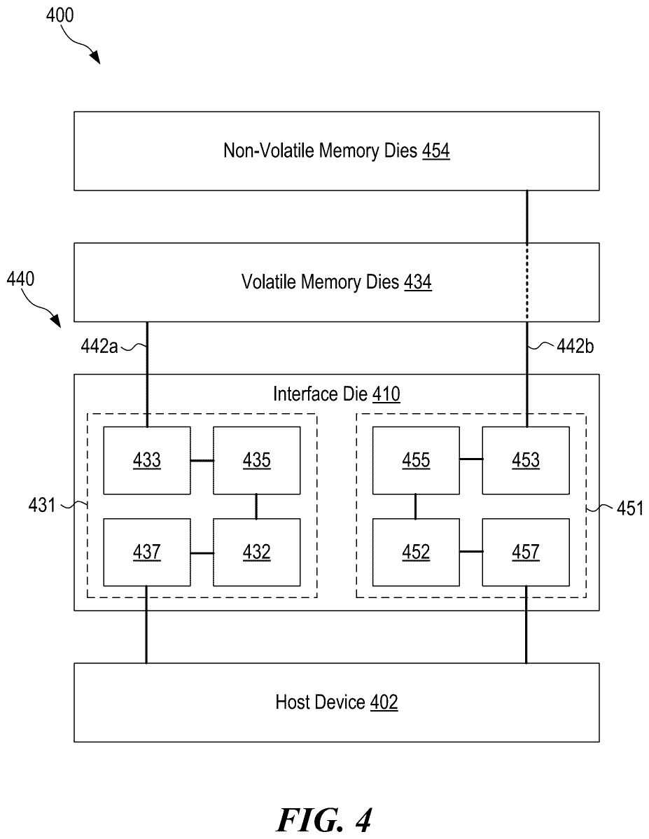

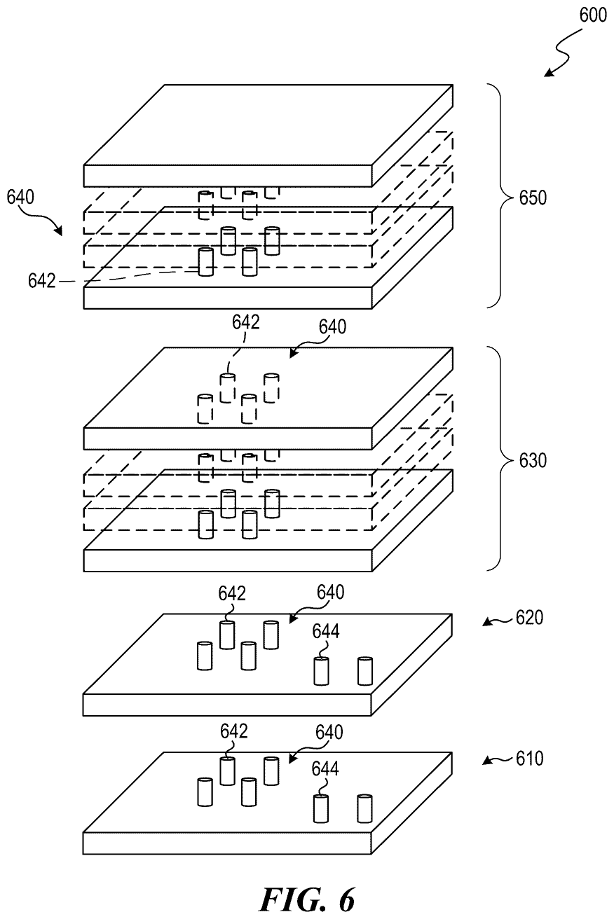

In some embodiments, as discussed in greater detail below with reference to FIGS. 4 and 6, each combined HBM device 330 can also include an interface die (not shown in FIG. 3). In such embodiments, functionalities found in and/or operations performed by the first controller die 332 and/or the second controller die 352 can be included in the interface die as opposed to forming separate dies (as illustrated in FIG. 3). In some embodiments, the functionalities found in and/or operations performed by the first controller die 332 and/or the second controller die 352 are included in the host device 320. This allows the interface die and/or the host device 320 to control the volatile memory dies 334 and/or the non-volatile memory dies 354 of the combined HBM device 330 in response to various read and write requests. The non-volatile memory dies 354 provide a relatively large, non-volatile storage (e.g., on the order of hundreds of gigabytes, a terabyte, and/or the like) within the SiP device 300. As a result, relatively large data sets and/or the like can be stored fully within the SiP device 300, reducing the need to retrieve data from an external storage.

For example, as discussed in more detail below, during operation of the SiP device 300, the host device 320 can send a request for a subset of a large data set to the combined HBM device 330 through the TSVs 338 of the TSV bus 340. The first controller die 332 can check whether the subset is stored in the volatile memory dies 334 and, if not, forward the request and/or generate a new request for the data to the second controller die 352 through the TSVs 338. The non-volatile memory dies 354 can then write a copy of the subset of the data to the volatile memory dies 334 through the TSVs 338, thereby allowing the combined HBM device 330 to send the subset of the data to the host device 320 for processing through the TSVs 338. Once the subset has been processed (and/or at various times during the processing), the host device 320 can write a result of the processing into the combined HBM device 330 through the TSVs 338. More specifically, the host device 320 can write the result to the volatile memory dies 334 which, in turn, can write the result to the non-volatile memory dies 354 through the TSVs 338. The host device 320 can then send a request for another subset of the data set to the combined HBM device 330, and so on. In some embodiments, the process can be repeated, as necessary, any number of times (e.g., when iteratively training a machine learning model on a data set). As a result, when a data set is available in the combined HBM device 330, the SiP device 300 is able to complete any number of iterations of a processing operation without communicating with an external storage component (e.g., via a PCI bus), thereby avoiding (or reducing the passages through) the bottleneck discussed in more detail above and increasing an overall processing speed of the SiP device 300.

In some embodiments, the volatile memory dies 334 act as a buffer for the non-volatile memory dies 354 to increase a response speed of the combined HBM device 330. For example, as discussed in more detail below, the combined HBM device 330 can receive a first request instructing the first controller die 332 and/or the second controller die 352 to load a subset of data into the volatile memory dies 334 from the non-volatile memory dies 354 for an upcoming request (e.g., when the host device 320 knows which data it will need next), then receive a second request instructing the first controller die 332 to send the data to the host device 320 from the volatile memory dies 334. By loading the subset of the data into the volatile memory dies 334 in response to the first request, the combined HBM device 330 can help reduce a response time to the second request, thereby further increasing the overall processing speed of the SiP device 300.

In some embodiments, the TSVs 338 directly couple the non-volatile memory dies 354 to the host device 30. The direct coupling between the non-volatile memory dies 354 and the host device 320 can allow a new subset of data to be loaded directly to the host device 320 at the start of a new operation (e.g., avoiding a buffer time associated with loading the subset into the volatile memory dies 334 then loading the subset into the host device 320). Additionally, or alternatively, the direct coupling between the host device 320 and the non-volatile memory dies 354 can allow the host device 320 to periodically save a state of the host device 320 directly to the non-volatile memory dies 354 to create a non-volatile backup of the current state (e.g., after a predetermined amount of time, after a processing milestone, and/or the like).

As further illustrated in FIG. 3, the host device 320 can be connected to the upper surface 312 of the base substrate via solder balls, micro bumps, posts (e.g., copper posts), metal-metal bonds, and/or any other suitable conductive bonds. Also, the SiP device 300 also includes interconnects 362 extending from the upper surface 312 of the base substrate 310 to a lower surface 314 of the base substrate 310. The interconnects 362 can provide an external connection for the host device 320. For example, the interconnects 362 can couple the host device 320 to an external component (e.g., a PCI bus coupled to an external storage, an external controller, and/or the like). Additionally, or alternatively, the interconnects 362 can couple the host device 320. Additionally, or alternatively, the interconnects 362 can couple the host device 320 to a testing pin on the lower surface 314 of the base substrate 310 (e.g., to allow the host device 320 and the combined HBM device 330 to be evaluated after the SiP device 300 is assembled).

However, because the combined HBM devices 330 are integrated on the upper surface 322 of the host device, in some embodiments, the SiP device 300 does not include the base substrate 310 (e.g., an interposer die) and additional components traditionally associated with the base substrate 310, such as route lines including metallization layers formed in one or more RDL layers of the base substrate 310 and/or one or more vias interconnecting the metallization layers and/or traces. The omission of the base substrate 310 can help simplify a construction of the SiP device 300 by limiting the number of different components and thereby reducing cost.

FIG. 4 is a simplified schematic diagram of a SiP 400 configured in accordance with some embodiments of the present technology. The SiP 400 can include a host device 402, an interface die 410, one or more volatile memory dies 434, one or more non-volatile memory dies 454, and a TSV bus 440. The interface die 410 can include a first set of components 431 coupling the volatile memory dies 434 to the host device 402 via first TSVs 442a included in the TSV bus 440, and a second set of components 451 coupling the non-volatile memory dies 454 to the host device 402 via second TSVs 442b included in the TSV bus 440. The first set of components 431 can include a first three-dimensional TSV input-and-output (3D TSV I/O) interface 433 coupled to the volatile memory dies 434, a first adapter 435 coupled to the first 3D TSV I/O interface 433, a first controller 432 coupled to the first adapter 435, and a second 3D TSV I/O interface 437 coupled between the first controller 432 and the host device 402. The second set of components 451 can include a third 3D TSV I/O interface 453 coupled to the non-volatile memory dies 454, a second adapter 455 coupled to the third 3D TSV I/O interface 453, a second controller 452 coupled to the second adapter 455, and a fourth 3D TSV I/O interface 457 coupled between the second controller 452 and the host device 402.

In the illustrated embodiment, the volatile memory dies 434 are stacked between the interface die 410 and the non-volatile memory dies 454. Therefore, the first set of components 431 can be directly coupled to the volatile memory dies 434 via the first TSVs 442a, and the second set of components 451 can be coupled to the non-volatile memory dies 454 via the second TSVs 442b that pass through the volatile memory dies 434.

In operation, the first controller 432 (e.g., a DRAM controller) can manage data transfer between the volatile memory dies 434 and the host device 402 in response to read and write requests. Similarly, the second controller 452 (e.g., a NAND controller) can manage data transfer between the non-volatile memory dies 454 and the host device 402 in response to read and write requests.

In some embodiments, the first controller 432 and/or the second controller 452 are included in the host device 402 instead. For example, the first adapter 435 and/or the second adapter 455 may remain included in the interface die 410, and the first controller 432 and/or the second controller 452 can be coupled to the first adapter 435 and/or the second adapter 455 via the first and/or second TSVs 442a, 442b, respectively.

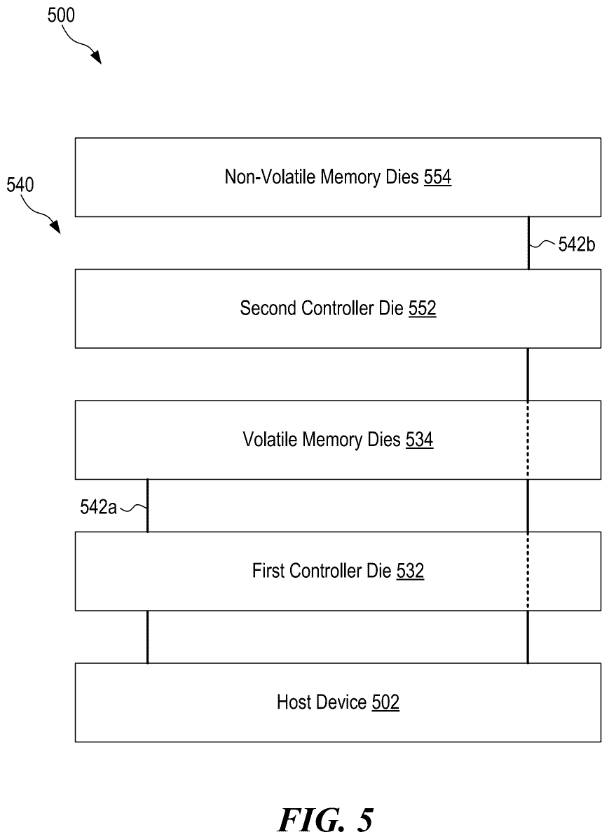

FIG. 5 is a simplified schematic diagram of a SiP 500 configured in accordance with some embodiments of the present technology. The SiP 500 can include a host device 502, a first controller die 532, one or more volatile memory dies 534, a second controller die 552, one or more non-volatile memory dies 554, and a TSV bus 540. Notably, unlike the SiP 400, the SiP 500 does not include an interface die (e.g., the interface die 410). In the illustrated embodiment, the first controller die 532 and the volatile memory dies 534 are stacked between (i) the host device 502 and (ii) the second controller die 552 and the non-volatile memory dies 554. Therefore, the first controller die 532 can be directly coupled to the volatile memory dies 534 and the host device 502 via first TSVs 542a included in the TSV bus 540. Also, the second controller die 554 can be directly coupled to the non-volatile memory dies 554 and indirectly coupled to the host device 502 via second TSVs 542b included in the TSV bus 540. As shown, the second TSVs 542b pass through the first controller die 532 and the volatile memory dies 534.

In operation, the first controller die 532 (e.g., a DRAM controller) can manage data transfer between the volatile memory dies 534 and the host device 502 in response to read and write requests. Similarly, the second controller die 552 (e.g., a NAND controller) can manage data transfer between the non-volatile memory dies 554 and the host device 502 in response to read and write requests.

FIG. 6 is a partially schematic exploded view of a combined HBM device 600 configured in accordance with some embodiments of the present technology. The combined HBM device 600 can be an example of the combined HBM devices 330 discussed above with reference to FIG. 3. In the illustrated embodiment, the combined HBM device 600 comprises a stack of dies that includes an interface die 610, a static random access memory (SRAM) die 620, one or more volatile memory dies 630 (four illustrated in FIG. 6), and one or non-volatile memory dies 650 (four illustrated in FIG. 6). Further, the combined HBM device 600 includes a shared TSV bus 640 communicatively coupling the interface die 610, the SRAM die 620, the volatile memory dies 630, and the non-volatile memory dies 650. The shared TSV bus 640 can include one or more individual TSVs 642 extending through the dies.

The interface die 610 can be a physical layer (“PHY”) that establishes electrical connections between the other dies and other components (e.g., the host device 320 of FIG. 3) through the shared TSV bus 640. The SRAM die 620 can provide volatile memory capacity in addition to the volatile memory dies 630. As shown, in addition to the TSVs 642 of the shared TSV bus 640, the SRAM die 620 can be coupled to the interface die 610 via TSVs 644 that do not extend to the volatile memory dies 630 or the non-volatile memory dies 650. In some embodiments, the vertical integration of the host device and the memory dies allows the interface die 610 to be omitted entirely, as discussed above with reference to FIG. 5.

In some embodiments, the combined HBM device 600 additionally includes one or more controller dies for controlling the volatile memory dies 630 and/or the non-volatile memory dies 650, as discussed above with reference to FIG. 5. The controller dies can be stacked adjacent the volatile memory dies 630 and/or the non-volatile memory dies 650. In some embodiments, the interface die 610 can include one or more controller dies for controlling the volatile memory dies 630 and/or the non-volatile memory dies 650, as discussed above with reference to FIG. 4. In some embodiments, the combined HBM device 600 does not include controllers (or controller dies), which can instead be included in a host device (not shown in FIG. 6).

The volatile memory dies 630 can be DRAM memory dies that provide low latency memory access to the combined HBM device 600 (e.g., acting as a buffer die for the combined HBM device 600). In contrast, the non-volatile memory dies 650 (sometimes referred to herein as a “secondary memory die,” “memory extension,” a “memory extension die,” and the like) can provide a non-volatile storage device (e.g., a NAND flash device) for the combined HBM device 600. Further, the non-volatile memory dies 650 can provide a significant extension of the available memory (e.g., two times, three times, four times, five times, ten times, or any other suitable increase in the memory capacity of the volatile memory dies 630). In a specific, non-limiting example, each of the volatile memory dies 630 can provide 4 GB of memory while each of the non-volatile memory dies 650 can provide 64 GB of memory. In this example, a SiP device (e.g., the SiP device 300 of FIG. 3) including the combined HBM device 600 can avoid the latency of loading memory from an external storage component (and through a low bandwidth communication channel) into the volatile memory dies 630 for each round of processing through the 256 GB of data that can be stored in the non-volatile memory dies 650.

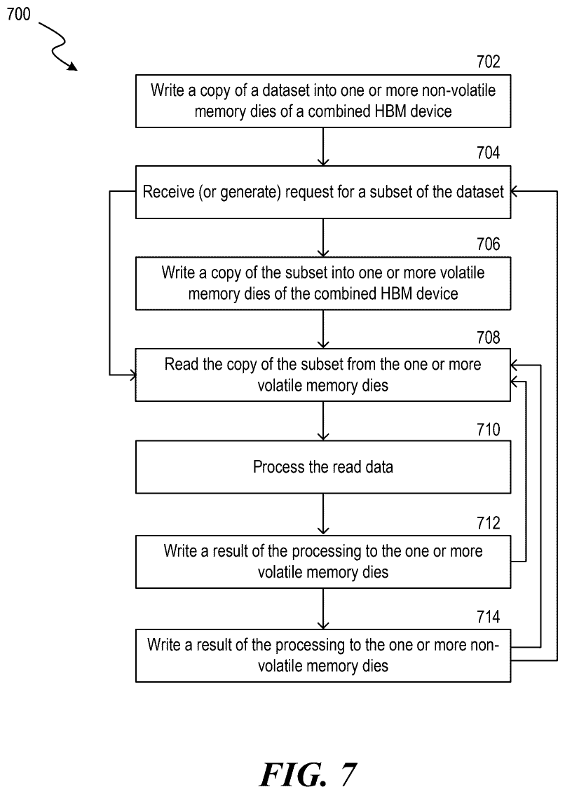

FIG. 7 is a flow diagram of a process 700 for operating a SiP device in accordance with some embodiments of the present technology. The process 700 can be completed by a controller in communication with the SiP device (e.g., a package controller) and/or on-board the SiP device (e.g., the host device 320 of FIG. 3, within the combined HBM device 330 of FIG. 3, and/or the like) to load, manage, and/or process data in the SiP device.

The process 700 begins at block 702 with writing data into one or more non-volatile memory dies (e.g., the non-volatile memory dies 354 of FIG. 3) of a combined HBM device (e.g., the combined HBM device 330 of FIG. 3). In some embodiments, the data is written from an external storage component into the non-volatile memory dies (e.g., via a PCI bus such as the third communication channel 256 of FIG. 2). In some such embodiments, the capacity of the non-volatile memory dies is large enough to store an entire data set for a complex computational operation (e.g., image and/or video rendering, AI/ML algorithms, and/or the like). In such embodiments, the data set must pass through a bottleneck to be loaded into the SiP device (e.g., through the PCI bus) only once. Afterward, the entire data set is available at a single location via a high bandwidth communication channel (e.g., the TSV bus 340 of FIG. 3) for any suitable number of iterations of the computational operation. In some embodiments, the SiP device includes multiple combined HBM devices and the data written into each combined HBM device is a partition of a larger data set. For example, a larger data set can be partitioned into two, three, four, and/or any other suitable number of parts for a corresponding number of combined HBM devices in a SiP and/or a corresponding number of SiP devices having one or more combined HBM devices. Additionally, or alternatively, the set of data can be partitioned according to an external requirement (e.g., according to a desired batch size for data in an AI/ML process, to maximize resource utilization during a computational process, and the like). In a specific, non-limiting example, a SiP device can include four combined HBM devices similar to the HBM devices 330 discussed above with reference to FIG. 3, each having a stack of non-volatile memory dies that provides 256 GB of memory. In this example, a data set with 1024 GB of data can be portioned into four partitions of 256 GB, each of which can be loaded into a corresponding combined HBM device to be accessed during the AI/ML process. In some embodiments, the data is written from another suitable external component (e.g., a bus component coupled to another electronic device, a data capture device, an input/output device, and/or the like), for example when the combined HBM device stores a primary copy (and/or only) of data used by an electronic device that includes the SiP device.

In some embodiments, the write operation at block 702 includes determining a role for the one or more non-volatile memory dies in the combined HBM device. For example, a first subset of the non-volatile memory dies can be assigned as core dies, a second subset of the non-volatile memory dies can be assigned as spare dies, and a third subset of the non-volatile memory dies can be assigned as error correction code (ECC) dies.

Because the write operation at block 702 requires data to move from an external storage component and/or another external device into the combined HBM device, the write operation can require the data to move through a relatively low bandwidth bus (e.g., on the order of 8 GB/s in the bottleneck described above with reference to FIG. 1). Consequently, the write operation can take several seconds to complete. However, as discussed in more detail below, the data is then available via a high bandwidth communication path within the SiP device, allowing the data to be used any number of times without going through the bottleneck again.

At block 704, the process 700 includes receiving (or generating) a request for a subset of the data in the combined HBM device. The request can be received from, for example, a host device (e.g., CPU/GPU) in a SiP device and/or any other suitable controller. Additionally, or alternatively, the request can be generated by a controller in the combined HBM device (e.g., by the interface die 410 of FIG. 4) in anticipation of the data being needed by an external component and/or based on a previous request from the external component. In some embodiments, receiving the request causes the combined HBM device (e.g., via a controller in the interface die) to check whether the requested subset of the data is stored in a volatile memory die in the combined HBM device. When the requested subset is found in a volatile memory die, the process 700 can continue to block 708 (e.g., when the subset is written to the volatile memory die in anticipation of the request), else the process 700 must continue to block 706.

At block 706, the process 700 includes writing a copy of the subset of the data (or causing the subset of the data to be written), from the non-volatile memory dies device, into one or more volatile memory dies in the combined HBM device. The write operation can use a portion of a TSV bus (e.g., the TSV bus 340 of FIG. 3) between the non-volatile memory dies and the volatile memory dies to write the requested subset via a high bandwidth communication path. As a result, the write operation at block 706 can be executed in a timeframe on the order of tens of microseconds, such that the subset is available almost instantly. Once stored in the HBM device, the subset of the data is available for typical use by a controller and/or processing unit via a high bandwidth communication path.

At block 708, the process 700 includes reading the subset of the data in volatile memory dies. The read operation can move a copy of the subset (and/or a portion of the subset) into a host device (e.g., the host device 320 of FIG. 3) via the TSV bus, which may extend between the host device and the combined HBM device. In some embodiments, the subset of the dataset requested at block 704 is access directly from the non-volatile memory dies. Therefore, in such embodiments, blocks 704 and 706 can be replaced by reading the subset of the data in the non-volatile memory dies.

At block 710, the process 700 includes processing the read subset of the data (e.g., at the host device 320 of FIG. 3). And at block 712, the process 700 can write a result of the processing (done at block 710) to the volatile memory dies through the high bandwidth communication path (e.g., the TSV bus 340 of FIG. 3). Because the read/write operations at blocks 708, 712 can communicate the data using the high bandwidth communication path, the subset of the data is available for processing within tens of microseconds, and/or the result of the processing is saved within tens of microseconds, such that the processing at block 710 is usually the limiting factor on the speed of the process 700 through blocks 708-712. After writing a result of the processing to the volatile memory dies at block 712, the process 700 can return to block 708 to repeat blocks 708-712 any suitable number of times (e.g., when the processing at block 710 is part of an AI/ML algorithm that iteratively processes the subset of the data), and/or can return to block 704 to receive (or generate) a request for a second subset of the data in the non-volatile memory dies and write the second subset of the data to the volatile memory dies for processing.

Additionally or alternatively, at block 714, the process 700 includes writing a result of the processing to the non-volatile memory dies. In some embodiments, the write at block 714 writes the result of the processing from the host device directly to the non-volatile memory dies. In some such embodiments, the write at block 714 can occur simultaneously (or generally simultaneously) with the write at block 712. Additionally, or alternatively, the write at block 714 can be executed instead of the write at block 712. In some embodiments, the write at block 714 writes the result of the processing from the volatile memory dies to the non-volatile memory dies (e.g., through the TSV bus 340 of FIG. 3). After writing a result of the processing to the non-volatile memory dies at block 714, the process 700 can return to block 708 to repeat blocks 708-712 any suitable number of times (e.g., when the processing at block 710 is a part of an AI/ML algorithm that iteratively processes the subset of the data, when the write at block 714 saves an intermediate result of the processing during a long processing operation, and/or the like), and/or can return to block 704 to receive (or generate) a request for a second subset of the data in the non-volatile memory dies and write the second subset of the data to the volatile memory dies for processing.

In various specific, non-limiting examples, the process 700 can be part of an AI/ML algorithm, a video rendering process, a high-resolution graphics rending process, various complex computer simulations, and/or any other suitable computing applications. In such embodiments, the CPU/GPU will typically call and/or refer to each subset of the data more than once. As a result, the SiP architectures discussed above with reference to FIGS. 2-6 allow the process 700 to avoid reading the data from a storage component (and through a low bandwidth communication channel) multiple times. Instead, the data is written into the non-volatile memory dies in the combined HBM device(s) once, then written to the volatile memory dies in the combined HBM device(s), and read any suitable number of times. While the initial writing operation is subject to the bottleneck constraints of the low bandwidth communication path from the storage component, each subsequent access of the subset of the data (and/or accessing each subset sequentially) uses a high bandwidth path. As a result, each subsequent use of the data can require tens of microseconds instead of one or more seconds, potentially increasing the speed of the processing operations by orders of magnitude.

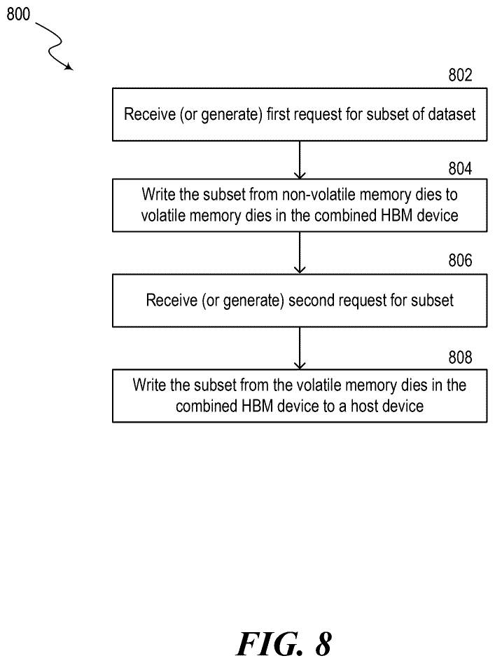

FIG. 8 is a flow diagram of a process 800 for operating a combined HBM device in accordance with some embodiments of the present technology. The process 800 can be implemented by a controller within an interface die of a combined HBM device (e.g., the interface die 410 of FIG. 4), a controller die stacked within the combined HBM device, a controller included in a host device (e.g., the host device 320 of FIG. 3), and/or another suitable controller in a SiP device.

The process 800 begins at block 802 with receiving (or generating) a first request for a subset of the data in the combined HBM device. The first request can be received from, for example, a CPU/GPU in a processing unit of a SiP device and/or any other suitable controller in anticipation of the data being needed by an external component (e.g., needed by the CPU/GPU) in the future. Purely by way of example, the first request can be received 10 cycles, 100 cycles, 1000 cycles, and/or any other suitable number of cycles before the anticipated need for the data. The first request allows the combined HBM device to check whether the requested subset of the data is available in volatile memory dies in the combined HBM device (e.g., the volatile memory dies 334 of FIG. 3). If not, at block 804, the process 800 includes writing the subset of the data from non-volatile memory dies (e.g., any of the non-volatile memory dies 354 of FIG. 3) to the volatile memory dies in the combined HBM device. As a result, the subset of the data is available in a faster component in response to the anticipated future need.

At block 806, the process 800 includes receiving (or generating) a second request for the subset of the data in the combined HBM device. The second request corresponds to the anticipated need for the subset of the data and can be received from, for example, a CPU/GPU in the processing unit of the SiP device. Responsive to receiving the second request, at block 808, the process 800 includes writing the subset of the data from the volatile memory dies in the combined HBM device to a host device (e.g., the host device 320 of FIG. 3) in the SiP (e.g., the SiP device 300 of FIG. 3). The write at block 808 can generally correspond to the read at block 708 of FIG. 7 to make the subset of data available for processing at the host device.

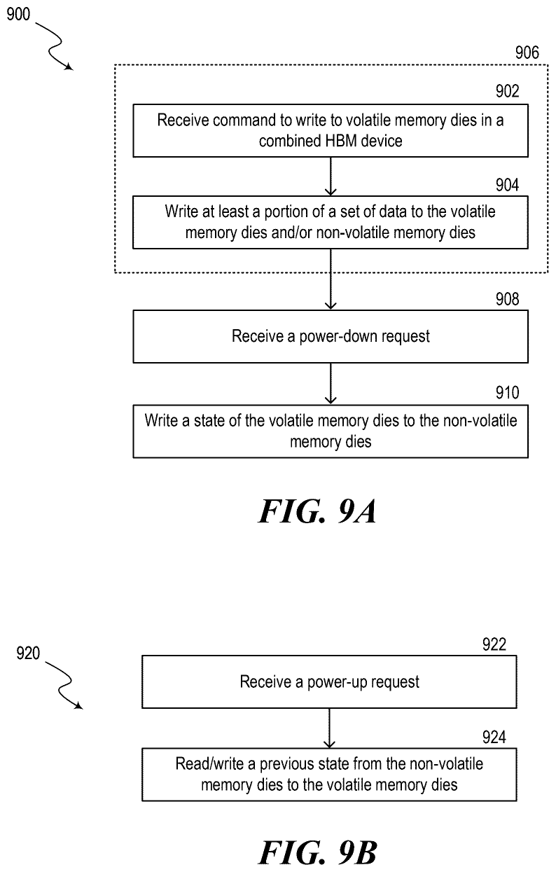

FIGS. 9A and 9B are flow diagrams of processes 900, 920 for powering a system-in-package device down and powering a system-in-package device up, respectively, using a combined high-bandwidth memory device in accordance with some embodiments of the present technology. The processes 900, 920 can be completed by a controller in communication with the SiP device (e.g., a package controller) and/or on-board the SiP device (e.g., included in the host device 320 or the combined HBM device 330 of FIG. 3).

The process 900 of FIG. 9A begins at block 902 by receiving (or generating) a command to write a set of data to one or more volatile memory dies in a combined HBM device (e.g., from a storage device separate from the SiP device). The command can be, for example, in response to a user's request to launch a computing application with the SiP device.

At block 904, the process 900 writes the set of data to the volatile memory dies (e.g., DRAM dies) in the combined HBM device, such that the portion (or all) of the set of data is available for typical processing. Because the non-volatile memory die and the volatile memory dies are both coupled to a shared TVS bus in the combined HBM device, the process 900 at block 904 can simultaneously write the set of data to the non-volatile memory die in the combined HBM device (optional). By writing the data to the non-volatile memory die, the process 900 can protect against data loss during a blackout or other sudden loss of power (e.g., damage to a power connection).

The process 900 can complete blocks 902 and 904 (collectively, block 906) any number of times during operation of the SiP to support typical processing in a semiconductor device. During the processing at block 906, the read/write operations can use the high bandwidth communication path to quickly communicate sets of data back and forth between the volatile memory dies and the processing components, allowing the read/write operations to not impose significant time constraints on the processing. Further, in some embodiments, the process 900 includes writing to the non-volatile memory die at block 906 to save a result of various processing operations, save a current state of the SiP device, the combined HBM device, and/or any related semiconductor device. Because the non-volatile memory die is coupled to a high bandwidth communication path (e.g., the shared TSV bus 340 of FIG. 3), the saves can protect against a blackout or other loss of power without requiring a significant time investment and/or pause in processing operations. Further, in some embodiments, because any write operation on the volatile memory dies automatically creates a save in the non-volatile memory dies by virtue of their mutual connection to TSVs in the shared TSV bus, the saves may not require any additional time.

At block 908, the process 900 includes receiving a power-down request (sometimes also referred to herein as an idle request). The power-down request can be received in response to an input from a user and/or another component of a system using the SiP device (e.g., to conserve power when an electronic device is running low on battery power and/or in response to a loss of power).

At block 910, the process 900 includes writing a state of the volatile memory dies (and/or any other suitable component of the semiconductor device, such as the L1 and L2 caches 226, 228 of FIG. 2) to the non-volatile memory die in the combined HBM device. Because the non-volatile memory die is coupled to the high bandwidth communication path, the write operation can complete within tens of microseconds (e.g., as opposed to one or more seconds to write the data to a traditional storage device, such as the storage device 140 of FIG. 1). As a result, the SiP device can comply with the power-down request within tens of microseconds, allowing the semiconductor device to save power, reduce losses of data when power is lost, and/or otherwise shut off quickly when requested.

Relatedly, the process 920 of FIG. 9B can begin at block 922 by receiving a power-up request (sometimes also referred to herein as a wake-up request). The power-up request can be received in response to an input from a user and/or another component of a system using the SiP device (e.g., another controller in a semiconductor device). And at block 924 the process 920 can read/write a previous state of the SiP device from the non-volatile memory die to the volatile memory dies and/or any other suitable components (e.g., the L1 and L2 caches 226, 228 of FIG. 2). Similar to the discussion above, because the non-volatile memory die is coupled to the high bandwidth communication path, the SiP device (and the corresponding semiconductor device) can respond to a power-up request within tens of microseconds (e.g., instead of the one or more seconds required to read/write from a traditional storage component). As a result, the SiP device (and the corresponding semiconductor device) can be ready for computational activities significantly faster than a conventional device.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “generally,” “approximately,” and “about” are used herein to mean within at least within 10 percent of a given value or limit. Purely by way of example, an approximate ratio means within ten percent of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Thus, computer-readable media can comprise computer-readable storage media (e.g., “non-transitory” media) and computer-readable transmission media.

It will also be appreciated that various modifications may be made without deviating from the disclosure or the technology. For example, the dies in the HBM device can be arranged in any other suitable order (e.g., with the non-volatile memory die(s) positioned between the interface die and the volatile memory dies; with the volatile memory dies on the bottom of the die stack; and the like). Further, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. For example, although discussed herein as using a non-volatile memory die (e.g., a NAND die and/or NOR die) to expand the memory of the HBM device, it will be understood that alternative memory extension dies can be used (e.g., larger-capacity DRAM dies and/or any other suitable memory component). While such embodiments may forgo certain benefits (e.g., non-volatile storage), such embodiments may nevertheless provide additional benefits (e.g., reducing the traffic through the bottleneck, allowing many complex computation operations to be executed relatively quickly, etc.).

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

I/We claim:

1. A system-in-package (SiP) device, comprising:
a processing unit;
a combined high-bandwidth (HBM) device carried by the processing unit, wherein the combined HBM device comprises:
one or more volatile memory dies; and
one or more non-volatile memory dies; and
a through silicon via (TSV) bus electrically coupled to each of the processing unit, the one or more volatile memory dies, and the one or more non-volatile memory dies.

2. The SiP device of claim 1, wherein the combined HBM device further comprises an interface die carried by the processing unit, and wherein the interface die includes:
a first adapter electrically coupled to the one or more volatile memory dies;
a first controller electrically coupled between the first adapter and the processing unit, wherein the first controller is configured to manage operation of the one or more volatile memory dies;
a second adapter electrically coupled to the one or more non-volatile memory dies; and
a second controller electrically coupled between the second adapter and the processing unit, wherein the second controller is configured to manage operation of the one or more non-volatile memory dies.

3. The SiP device of claim 2, wherein the interface die further includes:
a first three-dimensional TSV input-and-output (3D TSV I/O) interface electrically coupled between the one or more volatile memory dies and the first adapter, wherein the first 3D TSV I/O interface is coupled to the one or more volatile memory dies via a first set of TSVs of the TSV bus;
a second 3D TSV I/O interface electrically coupled between the first controller and the processing unit;
a third three-dimensional TSV input-and-output (3D TSV I/O) interface electrically coupled between the one or more non-volatile memory dies and the second adapter, wherein the third 3D TSV I/O interface is coupled to the one or more non-volatile memory dies via a second set of TSVs of the TSV bus, wherein the second set of TSVs pass through the one or more volatile memory dies; and
a fourth 3D TSV I/O interface electrically coupled between the second controller and the processing unit.

4. The SiP device of claim 1, wherein the combined HBM device further comprises:
a controller die carried by the processing unit, wherein the controller die is electrically coupled between the processing unit and the one or more volatile memory dies by the TSV bus, and wherein the controller die is configured to manage operation of the one or more volatile memory dies.

5. The SiP device of claim 1, wherein the combined HBM device further comprises:
a controller die carried by the one or more volatile memory dies, wherein the controller die is electrically coupled between the processing unit and the one or more non-volatile memory dies by the TSV bus, and wherein the controller die is configured to manage operation of the one or more non-volatile memory dies.

6. The SiP device of claim 1, wherein the processing unit includes a controller electrically coupled to the one or more volatile memory dies by the TSV bus, wherein the controller is configured to manage operation of the one or more volatile memory dies.

7. The SiP device of claim 1, wherein the processing unit includes a controller electrically coupled to the one or more non-volatile memory dies by the TSV bus, wherein the controller is configured to manage operation of the one or more non-volatile memory dies.

8. The SiP device of claim 1, wherein the SiP device does not include an interposer die electrically coupled to the processing unit.

9. The SiP device of claim 1, wherein the combined HBM device does not include an interface die between the processing unit and the one or more volatile memory dies.

10. A method, comprising:
generating a request for a subset of a set of data stored in a plurality of non-volatile memory dies in a combined high-bandwidth (HBM) device;
writing a copy of the subset to a plurality of volatile memory dies in the combined HBM device, wherein the plurality of non-volatile memory dies is carried by the plurality of volatile memory dies;
reading the subset from the plurality of volatile memory dies into a processing unit, wherein the plurality of volatile memory dies is carried by the processing unit;
processing, at the processing unit, the subset; and
writing a result of processing the subset to the plurality of volatile memory dies.

11. The method of claim 10, wherein writing the copy of the subset comprises writing the copy of the subset via a through silicon via (TSV) bus electrically coupled to each of the processing unit, the plurality of volatile memory dies, and the plurality of non-volatile memory dies.

12. The method of claim 10, wherein writing the copy of the subset comprises writing the copy of the subset via a through silicon via (TSV) bus electrically coupled to each of the processing unit, the plurality of volatile memory dies, and the plurality of non-volatile memory dies.

13. The method of claim 10, wherein generating the request for the subset is performed by a controller included in an interface die in the combined HBM device, wherein the interface die is carried by the processing unit, and wherein the plurality of volatile memory dies is carried by the interface die.

14. The method of claim 10, wherein generating the request for the subset is performed by a controller die included in the combined HBM device, wherein the controller die is carried by the processing unit, and wherein at least one of the plurality of volatile memory dies or the plurality of non-volatile memory dies is carried by the controller die.

15. The method of claim 10, wherein generating the request for the subset is performed by a controller included in the processing unit.

16. The method of claim 10, further comprising writing the result of processing the subset to the plurality of non-volatile memory dies.

17. A method, comprising:
writing a set of data to one or more volatile memory dies in a combined high-bandwidth (HBM) device through a through a silicon via (TSV) bus;
receiving, at a processing unit carrying the combined HBM device, a power down or idle request; and
in response to the power down or idle request, controlling the combined HBM device to write the set of data from the one or more volatile memory dies to one or more non-volatile memory dies in the combined HBM device through the TSV bus.

18. The method of claim 17, further comprising writing a copy of the set of data to the one or more non-volatile memory dies, through the TSV bus, before receiving the power down or idle request to store a backup of the set of data in the one or more non-volatile memory dies.

19. The method of claim 17, further comprising:
receiving, at the processing unit, a power up or wake up request; and
in response to the power up or wake up request, controlling the combined HBM device to write, through the TSV bus, the set of data from the one or more non-volatile memory dies back to the one or more volatile memory dies.

20. The method of claim 17, further comprising:
reading, through the TSV bus, the set of data from the one or more volatile memory dies to use at least a portion of the set of data in a computer processing operation; and
writing, through the TSV bus, a result of the computer processing operation to the one or more volatile memory dies.
